(19) United States
(12) Patent Application Publication
(10) Pub. No.: US 2025/0176274 A1
(43) Pub. Date: May 29, 2025

(54) TRANSISTOR, CONTROL METHOD THEREOF AND ELECTRONIC DEVICE

(71) Applicants: PowerWyse (Shenzhen) Co., Ltd., Shenzhen (CN); PowerWyse, Inc., Santa Clara, CA (US)

(72) Inventor: Tao Wei, Los Gatos, CA (US)

(73) Assignees: PowerWyse (Shenzhen) Co., Ltd., Shenzhen (CN); PowerWyse, Inc., Santa Clara, CA (US)

(21) Appl. No.: 18/629,650

(22) Filed: Apr. 8, 2024

(30) Foreign Application Priority Data
Nov. 29, 2023 (CN) 202311615631X

(51) Int. Cl. H01L 27/02; H01L 29/78; H03K 17/0412; H03K 17/06

(52) U.S. Cl. CPC H10D 89/10; H03K 17/04123; H03K 17/063; H10D 30/601; H10D 30/603

(57) ABSTRACT

A transistor, a control method thereof, and an electronic device are provided. The transistor includes a substrate, a source, a drain, a drain region, an insulating layer on the substrate and the drain region, and a gate on the insulating layer. The transistor further includes a plurality of conductive electrodes on one side of the insulating layer away from the substrate, and an active integrated circuit electrically connected to the plurality of conductive electrodes. The active integrated circuit is configured to dynamically adjust the switching characteristics of the transistor during the transition from a first switching state to a second switching state by controlling the plurality of conductive electrodes, thereby allowing for dynamic adjustment and improvement of the transistor's switching characteristics, resulting in low switching power loss and reduced electromagnetic interference in power transistors.

### RELATED APPLICATIONS

This application claims the benefit of priority of Chinese Application Number 202311615631X, filed on Nov. 29, 2023, and the content of which is incorporated herein by reference in its entirety.

### COPYRIGHT NOTICE

A portion of the disclosure of this patent document contains material which is subject to copyright protection. The copyright owner has no objection to the facsimile reproduction by anyone of the patent document or the patent disclosure, as it appears in the Patent and Trademark Office patent file or records, but otherwise reserves all copyright rights whatsoever.

### TECHNICAL FIELD

The present disclosure relates to the field of semiconductor technology, and in particular to a transistor, a control method thereof, and an electronic device.

### BACKGROUND

With the development of semiconductor technology, the application of power semiconductors is becoming increasingly widespread. For example, power transistors such as MOSFET (Metal-Oxide-Semiconductor Field-Effect Transistor) can be applied in various areas, such as power supplies, and power conversion systems, etc.

Switching characteristics, such as switching speed, are critical performance indicators of power transistors like MOSFET. A traditional power MOSFET is typically considered switch devices with fixed switching characteristics, incapable of dynamically adjusting the switching properties of the transistor. Therefore, how to dynamically adjust the switching characteristics of a transistor has become a pressing technical challenge that needs to be addressed.

The content in the Background section merely represents information known to the inventors personally. It does not imply that the mentioned information entered the public domain before the filing date of this disclosure, nor does it suggest that it can be considered as existing technology disclosed in the present disclosure.

### SUMMARY

The present disclosure provides a transistor, a control method thereof, and an electronic device, which can dynamically adjust and improve the switching characteristics of transistors, thereby enabling power transistors such as MOSFET to have relatively low switching power loss and relatively low EMI (Electromagnetic Interference).

In order to achieve the above objectives, some exemplary embodiments of the present disclosure employ the following technical solutions:

In a first aspect, some exemplary embodiments of the present disclosure provide a transistor, including: a substrate; a source, a drain, and a drain region on the substrate; an insulating layer on the substrate and the drain region; a gate on the insulating layer; a plurality of conductive electrodes arranged on a side of the insulating layer away from the substrate; and an active integrated circuit electrically connected to the plurality of conductive electrodes, where the active integrated circuit is configured to adjust switching characteristics of the transistor by controlling the plurality of conductive electrodes in a process of switching the transistor from a first switching state to a second switching state, the first switching state is an ON state and the second switching state is an OFF state, or the first switching state is an OFF state and the second switching state is an ON state.

In a second aspect, some exemplary embodiments of the present disclosure provide a control method for a transistor, including: providing a transistor including: a substrate, a source, a drain, and a drain region on the substrate, an insulating layer on the substrate and the drain region, a gate on the insulating layer, a plurality of conductive electrodes arranged on a side of the insulating layer away from the substrate, and an active integrated circuit electrically connected to the plurality of conductive electrodes; and controlling, by the active integrated circuit, the plurality of conductive electrodes to adjust switching characteristics of the transistor in a process of switching the transistor from a first switching state to a second switching state, where the first switching state is an ON state and the second switching state is an OFF state, or the first switching state is an OFF state and the second switching state is an ON state.

In a third aspect, some exemplary embodiments of the present disclosure provide an electronic device, including a transistor including: a substrate, a source, a drain, and a drain region on the substrate, an insulating layer on the substrate and the drain region, a gate on the insulating layer, a plurality of conductive electrodes arranged on a side of the insulating layer away from the substrate, and an active integrated circuit electrically connected to the plurality of conductive electrodes, where the active integrated circuit is configured to adjust switching characteristics of the transistor by controlling the plurality of conductive electrodes in a process of switching the transistor from a first switching state to a second switching state, the first switching state is an ON state and the second switching state is an OFF state, or the first switching state is an OFF state and the second switching state is an ON state.

According to the technical solutions of some exemplary embodiments disclosed in the present disclosure, on the one hand, by incorporating an active integrated circuit to control a plurality of electrodes arranged on the lightly doped drain region, it is possible to adjust and improve the switching characteristics of the transistor; on the other hand, since the active integrated circuit can dynamically control the potential of each electrode over time as needed, it can regulate the voltage and current waveforms within the transistor, thereby further enhancing the switching characteristics. This allows transistors, such as power MOSFETs, to have relatively low switching power losses and, at the same time, relatively low EMI.

### BRIEF DESCRIPTION OF THE DRAWINGS

In order to more clearly illustrate the technical solutions of the embodiments of the present disclosure, the following will briefly introduce the drawings for the description of some exemplary embodiments. Apparently, the accompanying drawings in the following description are some exemplary embodiments of the present disclosure. For a person of ordinary skill in the art, other drawings may also be obtained based on these drawings without creative efforts.

FIG. 1 is a schematic diagram of the switch loss of a transistor according to existing technologies;

FIG. 2 is a schematic diagram of the structure of a transistor according to some exemplary embodiments of the present disclosure;

FIG. 3 is a schematic diagram of the structure of an active integrated circuit according to some exemplary embodiments of the present disclosure;

FIG. 4a is a schematic diagram of the structure of a transistor according to some exemplary embodiments of the present disclosure;

FIG. 4b is a schematic diagram of the structure of a transistor according to some exemplary embodiments of the present disclosure;

FIG. 5 shows the waveforms formed by the on-resistance and current of a transistor when at least one conductive electrode is turned on and off (biased and unbiased) according to some exemplary embodiments of the present disclosure;

FIG. 6 shows the waveforms formed by the on-resistance and current of a transistor when a plurality of electrodes is sequentially turned on and off (biased and unbiased) according to some exemplary embodiments of the present disclosure;

FIG. 7 shows the waveforms formed by the on-resistance and current of a transistor when a plurality of electrodes is sequentially turned on and off (biased and unbiased) after the number of conductive electrodes is increased according to some exemplary embodiments of the present disclosure;

FIG. 8 shows the waveforms formed by the on-resistance and current of a transistor when a plurality of conductive electrodes is sequentially turned on (biased) according to the turning on (biasing) time of a gate according to some exemplary embodiments of the present disclosure;

FIG. 9 shows the waveforms formed by the on-resistance and current of a transistor when a plurality of conductive electrodes is sequentially turned off (unbiased) based at the turning off (unbiasing) time of a gate according to some exemplary embodiments of the present disclosure;

FIG. 10 is a schematic diagram of the structure of an electronic device according to some exemplary embodiments of the present disclosure; and

FIG. 11 is a schematic flowchart of a transistor control method according to some exemplary embodiments of the present disclosure.

### ELEMENT SYMBOLS IN THE DRAWINGS

100—transistor; 105—substrate; 110—gate; 120—insulating layer; 130—source; 140—body region; 150—drain region; 160—body; 170—drain; 310—conductive electrode.

### DETAILED DESCRIPTION

For a better understanding of the technical solutions in the embodiments of the present disclosure, detailed description of the technical solutions in some exemplary embodiments of the present disclosure will be provided below with reference to the accompanying drawings and specific examples. It should be understood that the specific features in the embodiments of the present disclosure are detailed descriptions of the technical solutions of the present disclosure, rather than limitations to the technical solutions of the present disclosure. In cases where there is no conflict, the technical features in the embodiments of the present disclosure can be combined with each other.

The terms used herein are only for the purpose of describing specific exemplary embodiments and are not restrictive. For instance, unless context explicitly indicates otherwise, the singular forms “one,” “a,” and “the” used herein may also include the plural forms thereof. When used in the present disclosure, the terms “comprise,” “comprising,” and/or “include” encompass the presence of the associated integers, steps, operations, elements, and/or components, but do not exclude the presence of one or more other features, integers, steps, operations, elements, components, and/or groups thereof; or additional features, integers, steps, operations, elements, components, and/or groups may be added to the system/method.

Considering the following description, the features of the present disclosure, along with other features, and the operations and functions of the related components of a structure, as well as the combination and economical manufacturing of parts, can be significantly improved. With reference to the drawings, all of these form part of the present disclosure. However, it should be understood that the drawings are only for illustrative and descriptive purposes and are not intended to limit the scope of the present disclosure. It should also be understood that the drawings are not drawn to scale.

Furthermore, the drawings herein are schematic illustrations. It can be understood that various elements, layers, and regions described in some exemplary embodiments of the present disclosure may have relative dimensions different from those shown in the accompanying drawings. Additionally, the shapes in the illustrations may undergo corresponding changes due to manufacturing techniques and/or tolerances. The embodiments of the present disclosure should not be interpreted as limited to specific shapes of the regions shown in the drawings but should include deviations in shape that may result from manufacturing processes. Therefore, the drawings are essentially schematic and are not intended to limit the scope of the present disclosure.

Switching speed is a key performance indicator of power MOSFETs. Switching speed mainly affects two crucial performance parameters of transistors: switching power loss and EMI. Switching power loss is mainly caused by the time (t) overlap of voltage (V_{ds}) and current (I_{ds}) from a drain to a source during the switching period of a transistor. When turning on or off the MOSFET, the gate needs to be charged or discharged. This process causes a time overlap between voltage (V_{ds}) and current (I_{ds}), resulting in power loss (Pₗₒₛₛ). The power loss Pₗₒₛₛ=∫ V_{ds}I_{ds}dt, with reference to the illustrations in FIGS. 1(a) and (b). The switching power loss mainly originates from the overlaps of V_{ds} and I_{ds} during a device's ON (conducting) and OFF (blocking) periods, which are represented in time as ΔTₒₙ (t₁-t₂) and ΔT_{off} (t₃-t₄), respectively. In addition, although fast switching can greatly reduce the overlaps of voltage and current, as well as switching power loss, the fast switching of transistors can cause stronger EMI signals from the device. In other words, the fast switching of transistors may also lead to worse EMI. In applications, the EMI of transistors needs to be maintained below acceptable levels.

To comply with industry standards, various methods have been employed in practical applications to reduce the electromagnetic interference (EMI) of transistors. Generally, there are trade-offs between EMI and other important performance parameters of transistors, such as device efficiency, size, and cost. Solutions to reduce EMI in transistors are typically implemented at the circuit level, and these solutions often require a certain degree of trade-off and compromise between the complexity of the system and device performance. In one technical approach, the switching speed of MOSFETs is slowed down by increasing the gate resistance, thereby reducing the switching gradient and the signal strength of EMI. However, this technical approach may also increase the switching power loss caused by the overlaps of voltage V_{ds} and current I_{ds} from the drain to the source.

There are several technical solutions to reduce EMI while simultaneously decreasing switching power loss, such as Zero Voltage Switching (ZVS) and Zero Current Switching (ZCS). In ZVS or ZCS technical solutions, the overlaps between the voltage V_{ds} and current I_{ds} from the drain to the source can be eliminated by adjusting the timing of switching voltage or current. This allows the switching power loss to be reduced to zero. These technical solutions are typically implemented at the application level through various circuit topologies, they can increase the complexity of the system. Additionally, in most cases, these technical solutions require the use of multiple transistors.

In the existing technologies, a passive circuit system is constructed using resistors or diodes on the dielectric layer of the Lightly Doped Drain (LDD) or drift region of a conventional power MOSFET. This circuit system is connected to the drain, gate, source, and body of the MOSFET and is designed to control the potential distribution on the LDD and adjust the internal electric field within the LDD. By appropriately controlling this passive circuit system, it is possible to optimize the carrier density in the LDD and reduce the resistance of the LDD. Since the circuit system is passive, the potential distribution mentioned above follows a predetermined function with the drain, gate, source, or body voltage as variables. As a result, the switching characteristics of the transistor are similar to those of a conventional power MOSFET, making it difficult to dynamically adjust the switching characteristics of the power MOSFET as needed. Therefore, there is a desire to provide a power transistor, such as a power MOSFET, with both relatively low switching power loss and relatively low EMI.

Based on the above content, some exemplary embodiments of the present disclosure propose a transistor and an electronic device. According to the technical solution thereof, on one hand, the inclusion of an active integrated circuit to control multiple electrodes set on the LDD region allows for the adjustment and improvement of the transistor's switching characteristics. On the other hand, since this active integrated circuit can dynamically control the potential of each electrode over time as needed, it can control the voltage and current waveforms within the transistor over time, further improving the switching characteristics of the transistor. This enables transistors, such as power MOSFETs, to have relatively low switching power loss and relatively low EMI.

The transistor according to some exemplary embodiments of the present disclosure can be applied to a series of power management systems, including power supplies for electronic equipment, power conversion systems, renewable energy systems, etc. The technical solutions of some exemplary embodiments of the present disclosure will be described in detail below with reference to the accompanying drawings.

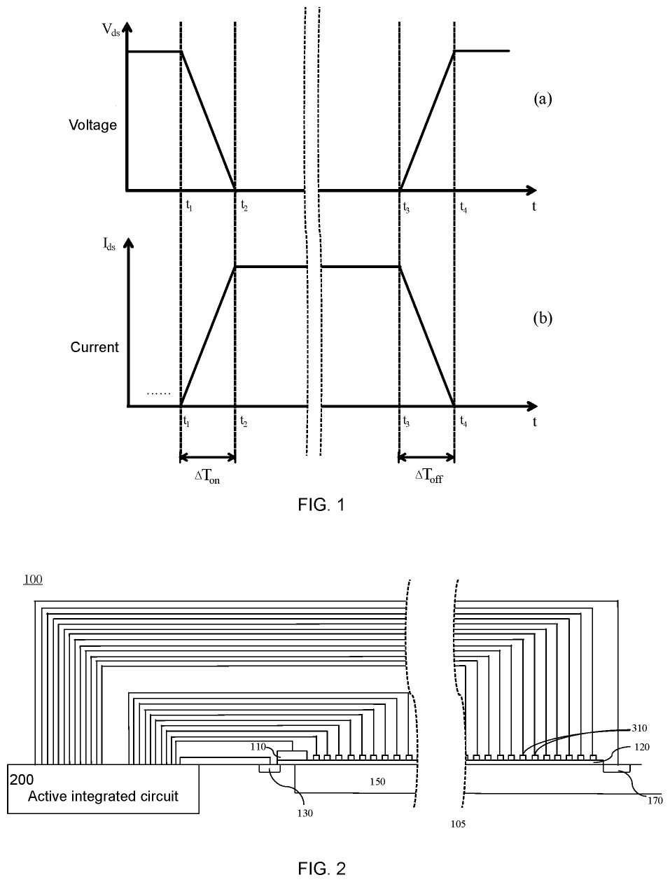

FIG. 2 is a schematic diagram of the structure of a transistor according to some exemplary embodiments of the present disclosure.

As shown in FIG. 2, a transistor 100 can include: a substrate 105, a source 130 located on the substrate 105, a drain 170, a drain region 150, an insulating layer 120 located on the substrate 105 and the drain region 150, and a gate 110 located on the insulating layer 120. Among them, the drain region 150 is a lightly doped drain region (LDD). That is, the doping levels of the source 130 and the drain 170 are at least one order of magnitude higher than the doping level of the drain region 150.

Moreover, the transistor 100 may also include: a plurality of conductive electrodes 310 arranged on one side of the insulating layer 120 away from the substrate 105; an active integrated circuit 200 electrically connected to the plurality of conductive electrodes 310. The active integrated circuit 200 is configured to as follows: during a process of the transistor 100 transitioning from a first switching state to a second switching state, it can adjust the switching characteristics of the transistor 100 by controlling the plurality of conductive electrodes 310. In this context, the first switching state is the ON state, and the second switching state is the OFF state; alternatively the first switching state is the OFF state, and the second switching state is the ON state.

In some exemplary embodiments, the active integrated circuit 200 may include at least one type of medium-low-voltage semiconductor active component, such as one or more of Metal-Oxide-Semiconductor Field-Effect Transistor (MOSFET), bipolar transistor, and Junction Field-Effect Transistor (JFET). During the process of the transistor 100 transitioning from the ON state to the OFF state, the active integrated circuit 200 may adjust the switching characteristics of the transistor 100 by controlling the plurality of conductive electrodes 310. Alternatively, during the process of the transistor 100 transitioning from the OFF state to the ON state, the active integrated circuit 200 may adjust the switching characteristics of the transistor 100 by controlling the plurality of conductive electrodes 310. Furthermore, the active integrated circuit 200 can be configured to: control the plurality of conductive electrodes 310, deplete charge carriers in the drain region 150 in the OFF state so as to increase the breakdown voltage of the transistor 100, and accumulate charge carriers in the drain region 150 in the ON state to reduce the ON-state resistance of the transistor 100.

Moreover, in some exemplary embodiments, the plurality of conductive electrodes 310 can be made of metal or a heavily doped semiconductor material(s). When voltage is applied to one or more conductive electrodes 310 in the ON state, the conductive electrodes 310 convert the lightly doped drain region (LDD) 150 therebelow into an accumulation mode. This significantly increases the charge carrier density in the lightly doped drain region 150 by 2 to 3 orders of magnitude, enhancing the conductivity of the MOSFET and reducing its ON-state resistance. When appropriately distributed voltage is applied to the plurality of conductive electrodes 310 in the OFF state, these electrodes can generate the required electric field, helping deplete charge carriers in the lightly doped drain region (LDD) 150 and enhancing the breakdown voltage of the MOSFET.

In accordance with the technical solution of the exemplary embodiments shown in FIG. 2, on the one hand, by incorporating an active integrated circuit to control the plurality of conductive electrodes positioned on the drain region, it is possible to adjust and improve the switching characteristics of the transistor. On the other hand, since the active integrated circuit can dynamically control the potential of each electrode over time, it can regulate the voltage and current waveforms inside the transistor over time. This dynamic adjustment of the switching characteristics enables the power MOSFET to have lower switching power loss while also lowering the EMI.

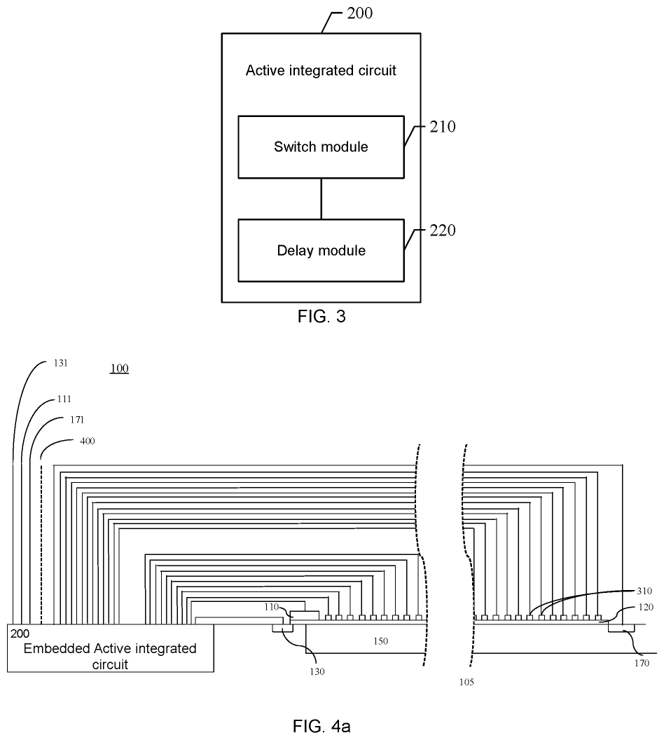

FIG. 3 is a schematic diagram of the structure of an active integrated circuit according to some exemplary embodiments of the present disclosure.

In the exemplary embodiments shown in FIG. 3, the active integrated circuit 200 can include: a switch module 210 and a delay module 220. The switch module 210 is electrically connected to the delay module 220. The switch module 210 is configured to control the ON and OFF of each of the plurality of conductive electrodes 310. The delay module 220 is configured to control an adjustable delayed time of at least one of the conductive electrodes 220.

Furthermore, the switch module 210 and the delay module 220 each include a medium-low-voltage circuit module widely used in the integrated circuit industry. For instance, the switch module 210 may include a medium-low-voltage switch circuit, and the delay module 220 may include a capacitor and inductor delay modules(s).

It should be noted that, while the illustration is based on the example of an active integrated circuit 200 including a medium-low-voltage circuit component(s), a person skilled in the art can understand that the active integrated circuit 200 may also include other suitable passive devices such as diodes, resistors, capacitors, or inductors, which are similarly within the scope of the exemplary embodiments of the present disclosure.

According to the technical solution in the exemplary embodiments of FIG. 3, an embedded active integrated circuit can achieve functions similar to passive circuit systems in the existing technologies. Additionally, it can dynamically control the potential of each terminal or electrode over time as needed, thereby further enhancing the switching characteristics of the power MOSFET.

Moreover, in some exemplary embodiments, the fundamental function of the embedded active integrated circuit is to control the internal source (130), drain (170), gate (110), and the plurality of conductive electrodes (310) to the respective optimal potentials thereof. Similar to the existing technologies, in the OFF state, the potential of the conductive electrodes remains constant along the LDD region to provide a constant electric field, so as to obtain an optimal breakdown voltage (BV) between the drain and source. In the ON state, the potential of the conductive electrodes (310) can drive the LDD region into an accumulation state, thereby reducing R_{dson}. Additionally, in some exemplary embodiments, the embedded active integrated circuit (200) can provide certain additional features, such as dynamically adjusting the conductivity or resistivity with the gate voltage, enhancing the switching performance, reducing the EMI, and minimizing the switching power loss.

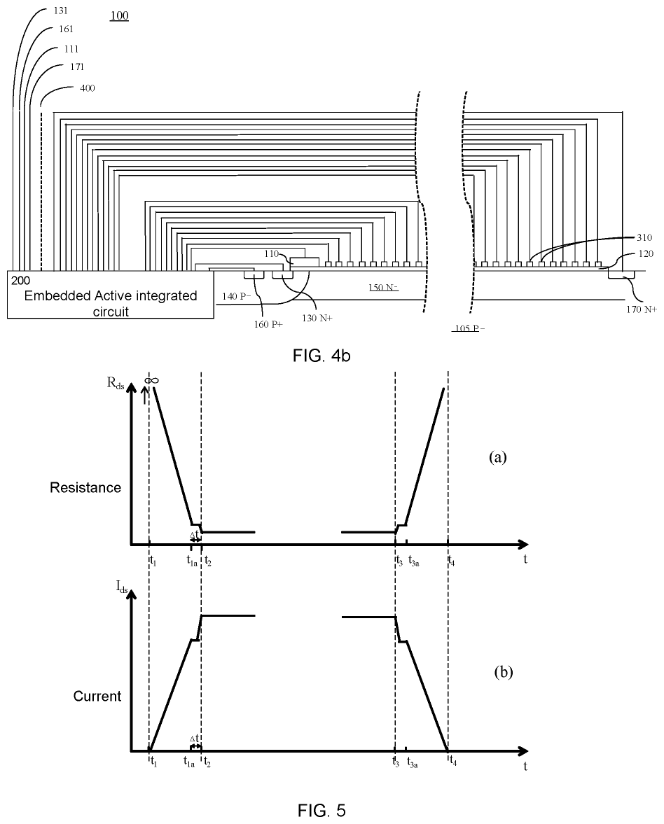

FIG. 4a is a schematic diagram of the structure of a transistor according to some exemplary embodiments of the present disclosure.

In some exemplary embodiments shown in FIG. 4a, the transistor 100 may also include a plurality of external terminals connected to the active integrated circuit 200. The plurality of external terminals can include an external source terminal 131, an external drain terminal 171, and an external gate terminal 111. These external terminals can be configured to control the source 130, the drain 170, and the gate 110, respectively, via the active integrated circuit 200.

Moreover, as shown in some exemplary embodiments shown in FIG. 4b, the transistor 100 may also include a body region 140. The body region 140 is located on the substrate 105 on the side of the drain region 150 away from the drain 170, with the source 130 situated within the body region 140. Additionally, there is a body 160 electrically connected to the active integrated circuit 200 and located on the body region 140.

In some exemplary embodiments, the transistor 100 can be an MOSFET device (MOSFET 100), and the active integrated circuit 200 is embedded in the transistor 100, such as in the substrate 105 of the transistor 100, forming the embedded active integrated circuit 200. The embedded active integrated circuit 200 is connected to and controlled by four external terminals, which include the external source terminal 131, an external body terminal 161, the external drain terminal 171, and the external gate terminal 111. These four external terminals play the same roles as the source 130, the body 160, the drain 170, and the gate 110, respectively, in the MOSFET.

In addition, the embedded active integrated circuit 200 is connected to and controls the drain 170, the gate 110, the source 130, and the body 160 within the MOSFET device structure. Furthermore, the embedded active integrated circuit 200 may also control the plurality of conductive electrodes 310 positioned on the dielectric layer above the LDD 150. In other words, the internal operations of the MOSFET are controlled by the embedded active integrated circuit 200. To distinguish them from the internal drain 170, gate 110, source 130 and body 160 of the MOSFET, the external terminals are labeled as an external drain 171, an external gate 111, an external source 131 and an external body 161, respectively, in the following text. With the external drain 171, the external gate 111, the external source 131 and the external body 161, the entire MOSFET appears to be a typical high-voltage power MOSFET from an external perspective.

As shown in some exemplary embodiments shown in FIG. 4b, the active integrated circuit 200 is embedded in the transistor 100, for example, embedded in the substrate 105, forming an embedded active integrated circuit. Taking the transistor 100 being an N-type MOSFET in the LDMOS (Lateral Diffused MOSFET) device structure as an example, the MOSFET may include at least: a P-type lightly doped semiconductor substrate 105; an N-type lightly doped drain region (LDD, or drift region) 150 located on the P-type lightly doped substrate 105; a P-type lightly doped body region 140 located on one side of the N-type lightly doped drain region 150 on the P-type lightly doped substrate 105; and an N-type lightly doped drain region 150 connected to the P-type lightly doped body region 140. In other words, the N-type lightly doped drain region 150 is adjacent to and attached to the P-type lightly doped body region 140, forming a mutual attachment.

In the N-type lightly doped drain region 150, there is an N+ type heavily doped drain 170 to support the applied high voltage. The P-type lightly doped body region 140 electrically isolates the source from the drain region and the drain. In the P-type lightly doped body region 140, there is a P+ type heavily doped body 160, located on one side of the N+ type heavily doped source region 130, away from the N-type lightly doped drain region 150. The P+ type heavily doped body 160 can provide a body-to-terminal electrical connection connected to other terminals. The plurality of conductive electrodes 310 are arranged on the insulating layer 120 above the N-type lightly doped drain region 150. The embedded active integrated circuit 200 may include conventional low-voltage MOSFETs, bipolar transistors, JFET transistors, diodes, resistors, capacitors, inductors, etc. The embedded active integrated circuit 200 is electrically connected to the drain 170, the gate 110, the source 130, the body 160, the conductive electrodes 310, as well as the external drain 171, the external gate 111, the external source 131, and the external body 161.

In some exemplary embodiments, as shown in FIGS. 4a and 4b, the embedded active integrated circuit 200 can be connected to an external control system via one or more additional external terminals 400 to provide additional operational control and flexibility. The additional external terminals 400 can indicate the embedded active integrated circuit to adjust the delay time accordingly, for example, controlling the adjustable delay time of at least one conductive electrode.

In some exemplary embodiments, the doping levels of the N+ type heavily doped source 130 and the N+ type heavily doped drain 170 can be at least one order of magnitude higher than the doping level of the P-type lightly doped body region 140 and N-type lightly doped drain region 150. In some exemplary embodiments, the doping levels of the N+ type heavily doped source 130 and the N+ type heavily doped drain 170 can be at least two orders of magnitude higher than the doping level of the P-type lightly doped body region 140 and N-type lightly doped drain region 150.

Moreover, the doping level of the N-type lightly doped drain region (LDD) 150 can vary depending on the material thereof. For example, as for silicon, it could be ≤1×10¹⁷/cm³, but it may differ in other materials. In silicon, the doping levels of the N+ type heavily doped source 130 and the N+ type heavily doped drain 170 can be greater than 1×10¹⁹/cm³.

The doped regions with relatively high doping concentration, such as the N+ type heavily doped source 130 and the N+ type heavily doped drain 170, are denoted as N+. The doping concentration thereof in silicon is approximately 1×10¹⁹/cm³ to 1×10²⁰/cm³. The P-type lightly doped body region 140 has a doping concentration in silicon of approximately 1×10¹⁷/cm³ to 1×10¹⁸/cm³. The N-type lightly doped drain region (LDD) 150 in silicon has a doping concentration of approximately 1×10¹⁵/cm³ to 1×10¹⁸/cm³. The P-type lightly doped semiconductor substrate 105 in silicon has a doping concentration of approximately 1×10¹⁴/cm³ to 1×10¹⁷/cm³.

In some exemplary embodiments, the P-type lightly doped semiconductor substrate 105 has a doping concentration similar to or lower than that of the P-type lightly doped body region 140 and N-type lightly doped drain region (LDD) 150. In other words, the doping concentrations in the N+ type heavily doped source and the N+ type heavily doped drain are at least two orders of magnitude higher than the doping concentration in the P-type lightly doped semiconductor substrate 105.

In some exemplary embodiments, the insulating layer 120 covers the N-type lightly doped drain region (LDD) 150 and a small portion of the P-type lightly doped body region 140. Specifically, the portion of the P-type lightly doped body region 140 covered by the insulating layer 120 is located above the N+ type heavily doped source 130 and N-type lightly doped drain (LDD) 150 therebetween. The gate 110 is positioned above the insulating layer 120 and overlaps vertically with the P-type lightly doped body region 140 and the small portion of the N+ type heavily doped source region 130.

It is noted that, while the exemplary embodiments of the present disclosure are described using an N-type high-voltage power MOSFET as an example, these embodiments are equally applicable to P-type high-voltage power MOSFETs. This can be achieved by exchanging the doping polarities of semiconductor substrate, body, source, drain, drain region, and electrodes doping as described in the above exemplary embodiments. It is known that in both N-type and P-type power MOSFETs, the electrodes and regions are doped with N-type and P-type conductivity types, respectively. In P-type power MOSFETs, the conductivity types of the corresponding electrodes and regions are simply swapped with those of N-type power MOSFETs.

Moreover, with reference to FIGS. 4a and 4b, when a positive voltage is applied to the gate 110, the top layer of the P-type substrate or the lightly doped body region 140 undergoes inversion and becomes N-type. This inversion creates a conductive channel between the N+ type heavily doped source 130, the N-type lightly doped drain region (LDD) 150, and the N+ type heavily doped drain 170. The transistor device operates in the ON state. The voltage on the gate 110 is set to zero to place the device in the OFF or cut-off state, allowing the application of high drain voltage in this state.

On the insulating layer 120, the plurality of conductive electrodes 310 are formed. These electrodes can be made of metal or heavily doped semiconductor materials. When a positive voltage is applied to one or more of the conductive electrodes 310 in the ON state, the conductive electrode 310 converts the underlying N-type lightly doped drain region (LDD) 150 into the accumulation mode, and increases the charge carrier density by 2 to 3 orders of magnitude, thereby greatly enhancing the conductivity of the transistor, such as a MOSFET, and reducing its ON-state resistance. When appropriately distributed voltage is applied to the conductive electrodes 310 in the OFF state, these electrodes can generate an electric field needed, assisting in depleting the charge carriers in the N-type lightly doped drain region (LDD) 150 and enhancing the breakdown voltage of the drain.

With reference to FIGS. 4a and 4b, the high-voltage N-type power MOSFET may include an embedded active integrated circuit 200, which connects and controls all internal terminals and electrodes. In the ON state, the embedded active integrated circuit 200 applies a positive voltage to one or more conductive electrodes, forming an accumulation layer in the N-type lightly doped drain region (LDD) 150, thereby reducing the ON-state resistance. In the OFF state, the embedded active integrated circuit 200 establishes a gradually changing voltage distribution in the N-type lightly doped drain region (LDD) 150, thereby depleting charge carriers and increasing the blockage voltage of the drain. Additionally, the design of the embedded active integrated circuit 200 can generate the needed waveforms when transitioning from the ON state to the OFF state, and vice versa, to enhance the switching performance of the transistor.

Below, a detailed description on adjusting the switching characteristics of the transistor in some exemplary embodiments of the present disclosure will be provided in conjunction with the accompanying drawings.

In some exemplary embodiments, the active integrated circuit 200 may also be configured as follows: during the transition of the transistor 100 from the OFF state to the ON state, following the turning on of the gate 110, turning on at least one conductive electrode 310 among the plurality of conductive electrodes 310 in an adjustable delay manner; alternatively, during the transition of the transistor 100 from the ON state to the OFF state, following turning off at least one conductive electrode 310 in an adjustable delay manner, turning off the gate 110.

FIG. 5 illustrates some N-type MOSFET exemplary embodiments according to the present disclosure, showing typical waveforms of the transistor's ON resistance and current when at least one conductive electrode is turned on or off. With reference to the left side of (a) in FIG. 5, during the turn-on process of the transistor 100, such as a MOSFET, from the OFF state to the ON state, at time t₁, the gate 110 is turned on with a positive voltage, and the ON resistance R_{ds} starts to decrease until time t₁ₐ. After a delay of Δt, the active integrated circuit 200 applies a positive voltage to one or more conductive electrodes 310, further reducing the ON resistance R_{ds} and increasing the current I_{ds}, as shown on the left side of (b) in FIG. 5.

Similarly, as shown on the right side of (a) in FIG. 5, during the turn-off process of the transistor 100 from the ON state to the OFF state, at time t₃, the active integrated circuit 200 turns off the voltage on one or more conductive electrodes 310; then, after a delay of Δt, at time t₃ₐ, the gate 110 is turned off, causing the ON resistance R_{ds} to stepwise increase and the current I_{ds} to stepwise decrease, as shown on the right side of (b) in FIG. 5.

In some exemplary embodiments, the active integrated circuit 200 may also be configured as follows, during the transition of the transistor 100 from the OFF state to the ON state, following turning on the gate 110, sequentially turning on each conductive electrode 310 among the plurality of conductive electrodes 310 in an adjustable delay manner; alternatively, during the transition of the transistor 100 from the ON state to the OFF state, after sequentially turning off each conductive electrode 310 among the plurality of conductive electrodes 310 in an adjustable delay manner, turning off the gate 110.

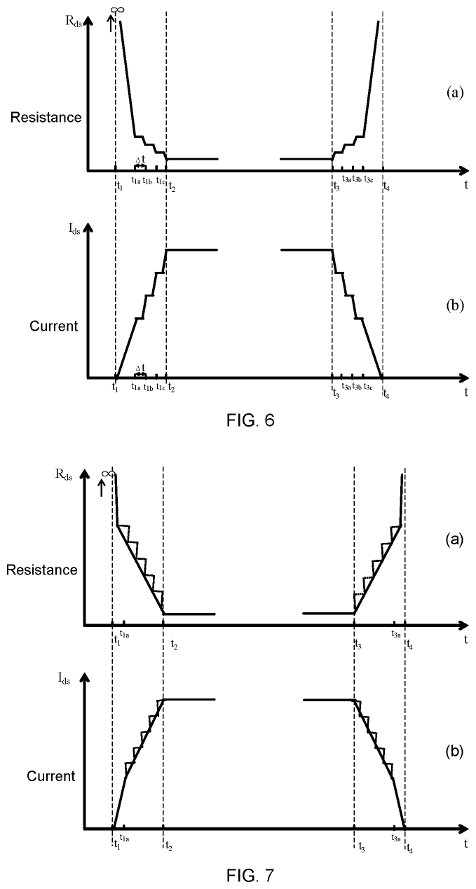

FIG. 6 illustrates some exemplary embodiments according to the present disclosure, showing waveforms of the ON resistance R_{ds} and current I_{ds} of the transistor when the plurality of electrodes are sequentially turned on and off. As shown on the left side of (a) in FIG. 6, during the turn-on process of the MOSFET from the OFF state to the ON state, at time t₁, first the gate 110 is turned on with a positive voltage, and the ON resistance R_{ds} starts to decrease, reaching stability at time t₁ₐ. After a time delay of Δt until t_{1b}, one conductive electrode 310 is then turned on, followed by sequentially turning on a plurality of electrodes 310 with a predetermined delay of Δt, causing the current I_{ds} to increase stepwise, as shown on the left side of (b) in FIG. 6.

Similarly, as shown on the right side of (a) in FIG. 6, during the turn-off process starting at time t₃, the active integrated circuit 200 first turns off the voltage on one conductive electrode 310. Subsequently, with a predetermined delay of Δt, a plurality of conductive electrodes 310 are sequentially turned off, causing the ON resistance R_{ds} to increase stepwise. Then, after a delay of Δt, the gate 110 is turned off, causing the current I_{ds} to decrease stepwise to reach zero, as shown on the right side of (b) in FIG. 6.

According to the technical solution in the above exemplary embodiments, during the switching process of the transistor, adding appropriate delays between the switches of various conductive electrodes among the plurality of conductive electrodes can reduce current gradients and electromagnetic interference. This allows the transistor, such as a power MOSFET, to have lower switching power loss while maintaining relatively low EMI.

FIG. 7 illustrates some exemplary embodiments according to the present disclosure, showing typical waveforms of the resistance and current of the transistor when multiple or all conductive electrodes are sequentially turned on and off, in the case of increasing the number of conductive electrodes. In some exemplary embodiments, after increasing the number of conductive electrodes 310, as shown on the left side of (a) in FIG. 7, during the turn-on process of the MOSFET from the OFF state to the ON state, at time t₁, the gate 110 is first turned on with a positive voltage, and the ON resistance R_{ds} starts to decrease, stabilizing at time t₁ₐ. Subsequently, with a predetermined delay, a plurality of conductive electrodes 310 can be sequentially turned on. As the number of electrodes increases, a gradually increasing charging process applies voltage to the conductive electrodes 310, allowing the ON resistance R_{ds} to evolve from the step function indicated by dashed lines to the smooth curve shown by solid lines. This results in a smooth and continuous increase in current, as shown on the left side of (b) in FIG. 7.

Similarly, as shown on the right side of (a) in FIG. 7, during the turn-off process starting at time t₃, the active integrated circuit 200 first turns off the voltage on one conductive electrode 310. Subsequently, with a predetermined delay, discharge is sequentially applied to turn off the conductive electrodes 310, allowing the ON resistance R_{ds} to evolve from the step function indicated by dashed lines to the smooth curve shown by solid lines. Then, the gate 110 is turned off, allowing the current I_{ds} to smoothly and continuously decrease, as shown on the right side of (b) in FIG. 7. Therefore, by controlling the plurality of conductive electrodes 310, it is possible to adjust the slope of the current change appropriately, thereby reducing EMI.

According to the technical solution in the above exemplary embodiments, by increasing the number of electrodes and applying appropriate delays when applying voltage to the electrodes, the step waveform of the ON resistance and current gradually approaches a continuous solid line with an appropriate slope, thereby achieving a reduction in EMI.

In some exemplary embodiments, the active integrated circuit 200 may also be configured as follows: during the transition of the transistor 100 from the OFF state to the ON state, following turning on the gate 110 and after a predetermined ON delay, sequentially turning on conductive electrodes 310 among the plurality of conductive electrodes 310 in an adjustable delay manner; alternatively, during the transition of the transistor 100 from the ON state to the OFF state, after sequentially turning off conductive electrodes 310 among the plurality of conductive electrodes 310 in an adjustable delay manner and after a predetermined OFF delay, the gate 110 is turned off.

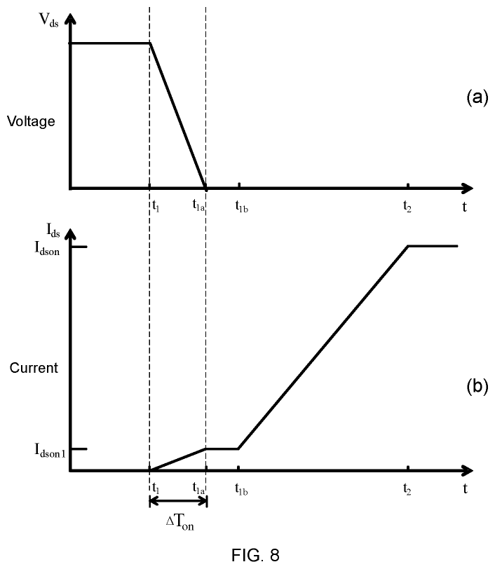

FIG. 8 illustrates some exemplary embodiments according to the present disclosure, showing waveforms of the ON resistance and current of the transistor when a plurality of conductive electrodes is sequentially turned on based on the time when the gate is turned on. As shown in FIG. 8, during the turn-on process of the MOSFET from the OFF state to the ON state, at time t₁, the gate 110 is turned on with a positive voltage, and the ON resistance R_{ds} starts to decrease, stabilizing at t₁ₐ. As shown in (a) of FIG. 8, after a time delay greater than ΔTₒₙ, and once the drain-to-source voltage V_{ds} has completely dropped, a plurality of conductive electrodes 310 is sequentially turned on. As shown in (b) of FIG. 8, a plurality of conductive electrodes 310 is sequentially turned on with a gradually increasing charging process, allowing the overlap of V_{ds} and I_{ds} to occur at a moment I_{dson1} significantly below the conventional ON current I_{dson}. Since the I_{ds} value at the overlap of V_{ds} and I_{ds} is relatively small, this ensures that the switching power loss can be significantly lower than the switching power loss under conventional conditions, achieving a near-zero current switch (near-ZCS).

According to the technical solution in the above exemplary embodiments, by shifting the overlapping time period ΔTₒₙ of the voltage V_{ds} and current I_{ds} to a range of significantly lower I_{ds}, a near-zero current switch (near-ZCS) can be achieved.

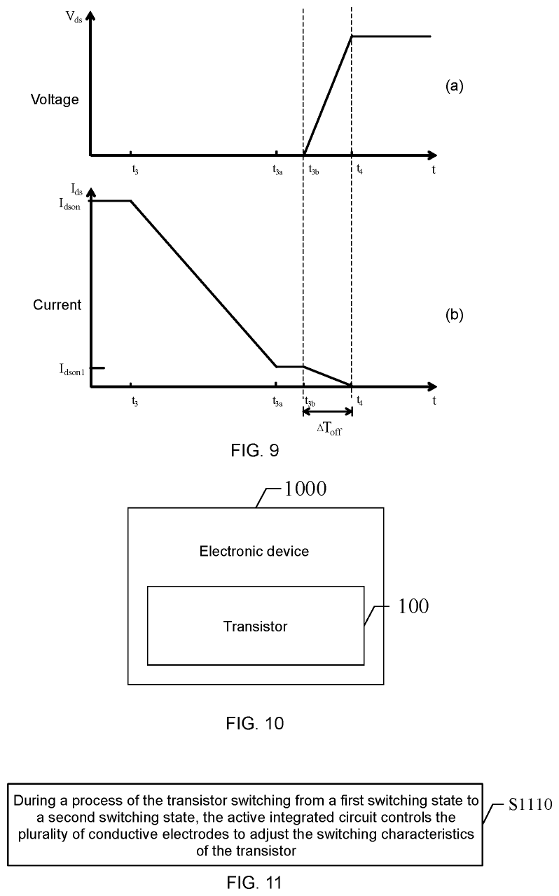

Similarly, FIG. 9 illustrates waveforms formed by the on-resistance and current of the transistor in some exemplary embodiments of the present disclosure when some or all conductive electrodes are sequentially turned off based on the gate turning off time. With reference to (a) and (b) in FIG. 9, during the turn-off process starting from time t₃, the active integrated circuit 200 turns off the voltage on one of the conductive electrodes 310. Subsequently, after a predetermined delay and gradual discharge, other conductive electrodes 310 are sequentially turned off, causing the current to gradually decrease until t₃ₐ. Then, after a delay time greater than ΔT_{off}, the gate 110 is turned off, allowing in the crossover of V_{ds} and I_{ds}, at I_{ds}=I_{dson1}, and I_{dson1} is significantly lower than the conventional conductive current I_{dson}. This also ensures that the switching power loss of the transistor is significantly lower than the conventional switching power loss, i.e., the switching power loss of the transistor is in a near-ZCS state. In other words, by shifting the time interval ΔT_{off} at which the voltage V_{ds} and current I_{ds} intersect to a current range where I_{ds} is significantly low, near-zero current switching (near-ZCS) can be achieved.

In accordance with the technical solution in the above-mentioned exemplary embodiments, by controlling multiple conductive electrodes via the active integrated circuit, it is possible to appropriately adjust the slope of electrical characteristics between t₁ and t₂, t₃ and t₄. For example, the slope of voltage, resistance, or current can be adjusted. This adjustment helps reduce the EMI of the transistor to an acceptable level. Consequently, it becomes possible to simultaneously lower both EMI and switching power loss in a single transistor device, such as a MOSFET device structure.

FIG. 10 is a schematic diagram of the structure of an electronic device according to some exemplary embodiments of the present disclosure.

With reference to FIG. 10, the electronic device 1000 may include a transistor 100. In some exemplary embodiments, the electronic device 1000 can be a charger or adapter for electronic devices, such as a mobile phone charger, toy charger, computer power supply, and so on.

It should be noted that while the electronic device is illustrated as a charger or adapter in some exemplary embodiments, a person skilled in the art would understand that the electronic device could also be other suitable power conversion devices, such as inverters or transformers. This is similarly within the scope of the embodiments described in the present disclosure.

The electronic device provided in some exemplary embodiments of the present disclosure may incorporate the transistor described in any of the above examples. Consequently, on the one hand, the inclusion of an active integrated circuit to control the plurality of electrodes situated in the lightly doped drain region allows for the adjustment and improvement of the transistor's switching characteristics. On the other hand, the active integrated circuit, capable of dynamically controlling the potential of each electrode over time, enables the control of voltage and current waveforms within the transistor, further enhancing the switching characteristics. The foregoing allows transistors, such as power MOSFETs, to have relatively low switching power loss while also exhibiting relatively low EMI.

Since the electronic device in some exemplary embodiments of the present disclosure incorporates the aforementioned transistor, it possesses all the advantages associated with the mentioned transistor.

It should be noted that the technical solution of the electronic device is based on the same concept as the transistor described above. The details not explicitly described in the technical solution of the electronic device can be referred to in the description of the technical solution of the transistor mentioned earlier.

FIG. 11 is a schematic flowchart of a transistor control method according to some exemplary embodiments of the present disclosure. The transistor includes a source, a drain, a drain region, an insulating layer located on the substrate and the drain region, a plurality of conductive electrodes positioned on a side of the insulating layer away from the substrate, and an active integrated circuit electrically connected to the plurality of conductive electrodes.

With reference to FIG. 11, in step S1110, during a process of the transistor switching from a first switching state to a second switching state, the active integrated circuit controls the plurality of conductive electrodes to adjust the switching characteristics of the transistor.

In some exemplary embodiments, the first switching state is an ON state, and the second switching state is an OFF state, or the first switching state is an OFF state, and the second switching state is an ON state. During the process of the transistor switching from a first switching state to a second switching state, the active integrated circuit 200 turns on or off at least one of the plurality of conductive electrodes 310 in an adjustable delay manner.

In some exemplary embodiments, during the process of the transistor 100 switching from the OFF state to the ON state, after the gate 110 is turned on, the active integrated circuit 200 may turns on at least one conductive electrode 310 in an adjustable delay manner. Alternatively, during the transition of the transistor 100 from the ON to the OFF state, after turning off at least one conductive electrode 310 in an adjustable delay manner, the gate 110 is turned off.

In the exemplary embodiments illustrated in FIG. 11, the technical solution has several advantages. On the one hand, by incorporating an active integrated circuit to control the plurality of electrodes situated in the lightly doped drain region, the transistor's switching characteristics can be adjusted and improved. On the other hand, the active integrated circuit, capable of dynamically controlling the potential of each electrode over time, allows for the regulation of voltage and current waveforms within the transistor. This dynamic control further enhances the switching characteristics of the transistor, enabling transistors such as power MOSFETs to exhibit relatively low switching power loss and relatively low EMI.

In some exemplary embodiments, the above adjusting the switching characteristics of the transistor by turning on or off at least one conductive electrode among the plurality of conductive electrodes in a controllable delayed manner may include: during the transition of the transistor from the OFF state to the ON state, turning on at least one conductive electrode among the plurality of conductive electrodes in a controllable delayed manner after turning on the gate; alternatively, during the transition of the transistor from the ON state to the OFF state, turning off at least one conductive electrode in a controllable delayed manner before turning off gate.

In some exemplary embodiments, the above adjusting the switching characteristics of the transistor by turning on or off at least one conductive electrode among the plurality of conductive electrodes in a controllable delayed manner may include: during the transition of the transistor from the OFF state to the ON state, after turning on the gate, sequentially turning on the plurality of conductive electrodes in a controllable delayed manner; alternatively, during the transition of the transistor from the ON state to the OFF state, after sequentially turning off the plurality of conductive electrodes in a controllable delayed manner, turning off the gate.

In some exemplary embodiments, the above adjusting the switching characteristics of the transistor by turning on or off at least one conductive electrode among the plurality of conductive electrodes in a controllable delayed manner may include: during the transition of the transistor from the OFF state to the ON state, after turning on the gate and after a predetermined conduction delay, sequentially turning on the plurality of conductive electrodes in a controllable delayed manner; alternatively, during the transition of the transistor from the ON state to the OFF state, after sequentially turning off the plurality of conductive electrodes in a controllable delayed manner, turning off the gate after a predetermined turn-off delay.

In some exemplary embodiments based on the above solution, the control method for the transistor may further include: adjusting the delay time of the controllable delayed manner for at least one conductive electrode among the plurality of conductive electrodes.

It is worth noting that the technical solution of the electronic device is of the same concept as the technical solution of the transistor mentioned above. The detailed contents not described in the technical solution of the electronic device can be referred to in the description of the technical solution of the transistor mentioned above.

In summary, in the transistor structure of, for example, a high-voltage power MOSFET device in some exemplary embodiments of the present disclosure, the addition of an embedded active integrated circuit allows for the control of the voltage and current waveforms over time within the transistor. This adjustment ensures that, whether in the ON state or OFF state, the I_{ds} within the overlap of V_{ds} and Idₛ can be adjusted to be lower than the conventional I_{ds}. This improvement enhances the switching performance, reduces the switching loss, and also helps mitigate EMI.

In some exemplary embodiments, the passive circuit is replaced with an embedded active integrated circuit. The embedded active integrated circuit includes active components commonly used in integrated circuits (ICs), such as MOSFETs, bipolar transistors, JFETs, as well as passive components like resistors, capacitors, inductors, and diodes. The embedded active integrated circuit is connected to and controls the voltage of the four terminals of the MOSFET, namely the gate, drain, source, and body terminals, as well as a plurality of conductive electrodes arranged in the LDD region. In addition to providing high breakdown voltage and high conductivity, as offered by passive circuits, the embedded active integrated circuit can also generate ideal waveforms under various conditions, a capability not possessed by passive circuits. Specifically, the embedded active integrated circuit can dynamically change the device's switching characteristics by controlling the variations of R_{ds} and I_{ds} waveforms over time, thereby achieving improved switching performance.

In some exemplary embodiments, the embedded active integrated circuit applies an appropriate voltage to each conductive electrode above or around the LDD region between the drain and source, creating a stable embedded electric field to deplete the charge carriers in the LDD region and enhance the blockage voltage in the OFF state. The conductive electrodes are separated from the LDD region by a layer of insulating dielectric material. In the ON state, one of the conductive electrodes is turned on so as to generate a local accumulation region in the LDD, reducing R_{dson}. By turning on some or all electrodes as well as the gate, the MOSFET is driven into an accumulation mode, where R_{dson} is significantly lower than the non-accumulation mode with only the gate on. The R_{dson} in the accumulation mode can be an order of magnitude lower than that in a non-accumulation mode. The accumulation mode occurs when some or all electrodes and the gate are turned on, while the non-accumulation mode occurs when only the gate is turned on. With the forgoing features, the embedded active integrated circuit can effectively control the switching waveform of the MOSFET, rendering it to have more desirable switching characteristics.

During the transistor switching process, when the gate voltage is turned on or off, the embedded active integrated circuit applies voltage at different times to each conductive electrode in the gate and the LDD region. This temporal variation results in a step function response in R_{dson}, which, in turn, causes a step function response in I_{ds}. This step function response can be utilized to enhance the switching performance of the MOSFET.

In more detail, when the transistor device switches from the OFF state to the ON state, an external gate voltage is applied to the transistor device. The embedded active integrated circuit first provides voltage to the gate and then sequentially provides voltage to individual conductive electrodes in the LDD region with a timed delay. The delay for each conductive electrode causes R_{dson} to gradually decrease over time, resulting in a gradual increase in I_{ds}, effectively reducing the magnitude of EMI. By adjusting the delay time, the embedded active integrated circuit can optimize the current gradient to improve EMI.

Conversely, when the transistor device switches from the ON state to the OFF state, the embedded active integrated circuit sequentially turns off the conductive electrodes with an appropriate delay. This causes R_{dson} to gradually increase, resulting in a gradual decrease in I_{ds}, thereby effectively reducing the magnitude of EMI. By adjusting the delay time, the embedded active integrated circuit can optimize the current gradient to further improve EMI.

Furthermore, during the charging or discharging of the gate, the MOSFET may experience significant variations in V_{ds}, causing an overlap between V_{ds} and I_{ds}. This overlap is a major source of switching power loss. The exemplary embodiments described herein enable the device to turn on or off only in the non-accumulation mode. In such a case, the current can be an order of magnitude lower than that in the normal accumulation conduction mode. The overlap between V_{ds} and I_{ds} occurs only at low currents, making the transistor device approach the ideal zero-current switch (near-ZCS), thereby resulting in low switching power loss.

In some exemplary embodiments, in order to achieve near-ZCS in the ON state, the embedded active integrated circuit first turns on the gate. The plurality of conductive electrodes on the LDD is turned on only after the gate is fully charged and V_{ds} has completely dropped, and then it enters the accumulation conduction mode. Since I_{ds} is at an extremely low conduction current when the overlap of V_{ds} and Idₛ occurs, near-ZCS can be achieved.

Similarly, in order to achieve near-ZCS in the OFF state, the embedded active integrated circuit first turns off the plurality of conductive electrodes on the LDD; the gate is turned off only after the conductive electrodes are completely discharged and in the non-accumulation mode, at which point V_{ds} begins to increase. Since I_{ds} is at an extremely low conduction current when the overlap of V_{ds} and Idₛ occurs, near-ZCS can be achieved.

According to the technical solution of the exemplary embodiments disclosed herein, by progressively turning on and off the plurality of conductive electrodes, EMI can be reduced. At the same time, near-ZCS can be achieved with appropriate time variations. Some exemplary embodiments of the present disclosure provide a solution for simultaneously achieving low EMI and low switch loss in a single MOSFET device.

In some exemplary embodiments, the transistor device can be controlled with more external terminals than the traditional 4 electrode terminals (drain, gate, source, and body). The additional terminals can instruct the embedded active integrated circuit to adjust the delay time accordingly. Therefore, the transistor device disclosed herein can be controlled with new or predefined switching modes to meet specific application requirements.

In some exemplary embodiments, the transistor structure can be extended to a three-dimensional (3D) structure scheme. A three-dimensional structure can significantly increase the difference in I_{ds} between the accumulation and non-accumulation modes, thereby further improving the switching power loss of the device when operating near-ZCS.

Some exemplary embodiments of the present disclosure provide a high-voltage power MOSFET. The high-voltage power MOSFET includes a semiconductor substrate doped with a first conductive type, a source doped with a second conductive type on the substrate, a drain doped with the second conductive type on the substrate, a drain region doped with the second conductive type spanning across a body and the drain. The doping levels of the source and drain are at least one order of magnitude higher than that of the body and the drain region. The body is doped with the first conductive type and separates the source from the drain and the drain region. An insulating layer is positioned on a portion of the body and above the drain region. The gate is located above the insulating layer and a portion of the source. In addition to the drain, gate, source and body, a plurality of conductive electrodes on the insulating layer are connected to an active integrated circuit in the transistor. In the OFF state, the embedded active integrated circuit generates a voltage distribution in the drain region to deplete carriers, enhancing the breakdown voltage. In the ON state, it generates accumulation carriers to reduce the on-state resistance. Under the control of the embedded active integrated circuit, the turn-on of the MOSFET follows the following sequence: first, the gate is turned on, then after an appropriate delay, the electrodes are sequentially turned on at specific time intervals to reduce EMI and turn-on switching power loss. In the shutdown process of the MOSFET, the electrodes are first turned off at specific time intervals, then after an appropriate delay, the gate is finally turned off, reducing EMI and shutdown switching power loss. The active integrated circuit in the transistor is connected via conductive metal lines to form active and passive components, generating the above voltage patterns and waveforms. Active components include MOSFETs, transistors, JFET transistors, diodes, while passive components include resistors, capacitors, inductors, and the like. The embedded active integrated circuit mainly includes traditional medium-low-voltage electronic switches and delay modules widely used in the semiconductor industry. Additionally, the transistor can be extended to a three-dimensional structure scheme to increase accumulation effects and further reduce switching power loss. Moreover, the transistor device can be controlled with more external terminals than the traditional 4 electrode terminals (drain, gate, source and body), thereby meeting specific application requirements.

Furthermore, when the first conductive type is P-type, the second conductive type is N-type, and the high-voltage power MOSFET is a high-voltage N-type power MOSFET. Conversely, when the first conductive type is N-type, the second conductive type is P-type, and the high-voltage power MOSFET is a high-voltage P-type power MOSFET.

The above has described some specific exemplary embodiments of the present disclosure. Other embodiments are also within the scope of the claims. In some cases, actions or steps set forth in the claims can be performed in an order different from the sequence described in the embodiments and still achieve the desired results. Additionally, the processes depicted in the drawings do not necessarily require a specific or continuous sequence to achieve the desired results. In certain embodiments, multitasking and parallel processing are also possible or advantageous.

In summary, after reading the detailed contents disclosed, a person skilled in the art can understand that the aforementioned detailed contents are presented by way of example only and are not restrictive. Although not explicitly stated herein, a person skilled in the art can appreciate it that this disclosure encompasses various changes, improvements, and modifications to the embodiments. These changes, improvements, and modifications are intended to be proposed and are within the ranges and scopes of the exemplary embodiments of the present disclosure.

In the above description, when elements such as layers, regions, or substrates are referred to as being “on” another element, it can mean that they are directly on that other element, or they may also be positioned with an intermediate element. Additionally, relative terms such as “inner,” “outer,” “above,” “below,” “within,” “out of,” and similar terms in this document can be used to describe the relative relationship between one layer and another region.

Moreover, certain terms have been used to describe certain exemplary embodiments. For example, “an embodiment,” “one embodiment,” and/or “some embodiments” mean that features, structures, or characteristics described in conjunction with that embodiment(s) may be included in at least one embodiment. Therefore, it should be emphasized and understood that references to “an embodiment” or “one embodiment” or “alternative embodiment” in various parts of the present disclosure do not necessarily refer to the same embodiment. Moreover, specific features, structures, or characteristics may be appropriately combined in one or more embodiments of the present disclosure.

It should be understood that, in the foregoing description of embodiments of the present disclosure, to aid in understanding a feature, for the purpose of simplifying the disclosure, various features may be combined in a single embodiment, drawing or description thereof. However, this is not to say that the combination of these features is mandatory, and a person skilled in the art may well extract some of these features to understand them as separate embodiments while reading this disclosure. In other words, embodiments in this disclosure can also be understood as an integration of multiple sub-embodiments. The content of each sub-embodiment is valid when it includes fewer features than all the features disclosed in a single aforementioned embodiment.

Each patent, patent application, publication of a patent application, and other materials, such as articles, books, specifications, publications, documents, articles, etc., cited herein, except for any historical prosecution documents to which it relates, which may be inconsistent with or any identities that conflict, or any identities that may have a restrictive effect on the broadest scope of the claims, are hereby incorporated by reference for all purposes now or hereafter associated with this document. Furthermore, in the event of any inconsistency or conflict between the description, definition, and/or use of a term associated with any contained material, the term used in this document shall prevail.

Finally, it should be understood that the exemplary embodiments disclosed herein are an explanation of the principles of the embodiments of the present disclosure. Other modified embodiments are also within the scope of the present disclosure. Therefore, the embodiments disclosed herein are only exemplary and not limiting. A person skilled in the art may adopt alternative configurations to implement the applications described herein based on the exemplary embodiments disclosed in the present disclosure. Hence, the embodiments of the present disclosure are not limited to the exemplary embodiments described herein.

What is claimed is:

1. A transistor, comprising:
a substrate;
a source, a drain, and a drain region on the substrate;
an insulating layer on the substrate and the drain region;
a gate on the insulating layer;
a plurality of conductive electrodes arranged on a side of the insulating layer away from the substrate; and
an active integrated circuit electrically connected to the plurality of conductive electrodes, wherein
the active integrated circuit is configured to adjust switching characteristics of the transistor by controlling the plurality of conductive electrodes in a process of switching the transistor from a first switching state to a second switching state, the first switching state is an ON state and the second switching state is an OFF state, or the first switching state is an OFF state and the second switching state is an ON state.

2. The transistor according to claim 1, wherein to adjust the switching characteristics of the transistor by controlling the plurality of conductive electrodes, the active integrated circuit is further configured to:
control the plurality of conductive electrodes to deplete charge carriers in the drain region in the OFF state to increase a breakdown voltage of the transistor, and to accumulate the charge carriers in the drain region in the ON state to reduce an on-resistance of the transistor.

3. The transistor according to claim 1, wherein to adjust the switching characteristics of the transistor by controlling the plurality of conductive electrodes, the active integrated circuit is further configured to:
adjust the switching characteristics of the transistor by turning on or off at least one conductive electrode in an adjustable delay manner.

4. The transistor according to claim 3, wherein to adjust the switching characteristics of the transistor by controlling the plurality of conductive electrodes, the active integrated circuit is further configured to:
turn on the at least one conductive electrode in the adjustable delay manner following turning on the gate in a process of switching the transistor from the OFF state to the ON state; or
turn off the gate before turning off the at least one conductive electrode in the adjustable delay manner in a process of switching the transistor from the ON state to the OFF state.

5. The transistor according to claim 3, wherein to adjust the switching characteristics of the transistor by controlling the plurality of conductive electrodes, the active integrated circuit is further configured to:
sequentially turn on the plurality of conductive electrodes in the adjustable delay manner following turning on the gate in a process of switching the transistor from the OFF state to the ON state; or
sequentially turn off the plurality of conductive electrodes in the adjustable delay manner before turning of the gate in a process of switching the transistor from the ON state to the OFF state.

6. The transistor according to claim 3, wherein the active integrated circuit is further configured to:
sequentially turn on the plurality of conductive electrodes in the adjustable delay manner after turning on the gate and following a predetermined turn-on delay in a process of switching the transistor from the OFF state to the ON state; or
turn off the gate following a predetermined turn-off delay after sequentially turning off the plurality of conductive electrodes in the adjustable delay manner in a process of switching the transistor from the ON state to the OFF state.

7. The transistor according to claim 3, wherein the active integrated circuit is further configured to:
adjust a delay time in the adjustable delay manner of the at least one conductive electrode.

8. The transistor according to claim 1, wherein the active integrated circuit is embedded in the transistor to form an embedded active integrated circuit.

9. The transistor according to claim 1, wherein the active integrated circuit is electrically connected to the source, the drain and the gate, and is configured to control the source, the drain and the gate.

10. The transistor according to claim 9, further comprising:
a plurality of external terminals electrically connected to the active integrated circuit, wherein
the plurality of external terminals included: an external source terminal, an external drain terminal and an external gate terminal, and plurality of external terminals is configured to respectively control the source, the drain and the gate via the active integrated circuit.

11. The transistor according to claim 1, wherein the active integrated circuit includes at least one of a metal oxide semiconductor field effect transistor (MOSFET), a bipolar transistor, or a junction field effect transistor.

12. The transistor according to claim 3, wherein the active integrated circuit includes a switch module and a delay module;
the switch module is electrically connected to the delay module, wherein
the switch module is configured to control the ON and OFF of each of the plurality of conductive electrodes, and
the delay module is configured to control a delay time in the adjustable delay manner of at least one conductive electrode.

13. The transistor according to claim 1, further comprising:
a body region on a side of the drain region on the substrate away from the drain, the source being arranged in the body region; and
a body pole in the body region and is electrically connected to the active integrated circuit.

14. The transistor according to claim 1, wherein the transistor is a power MOSFET.

15. A control method for a transistor, comprising:
providing a transistor including:
a substrate,
a source, a drain, and a drain region on the substrate,
an insulating layer on the substrate and the drain region,
a gate on the insulating layer,
a plurality of conductive electrodes arranged on a side of the insulating layer away from the substrate, and
an active integrated circuit electrically connected to the plurality of conductive electrodes; and
controlling, by the active integrated circuit, the plurality of conductive electrodes to adjust switching characteristics of the transistor in a process of switching the transistor from a first switching state to a second switching state, wherein
the first switching state is an ON state and the second switching state is an OFF state, or the first switching state is an OFF state and the second switching state is an ON state.

16. The method according to claim 15, wherein the controlling of the plurality of conductive electrodes to adjust switching characteristics of the transistor includes:
adjusting the switching characteristics of the transistor by turning on or off at least one conductive electrode in an adjustable delay manner.

17. The method according to claim 16, wherein the adjusting of the switching characteristics of the transistor by turning on or off at least one conductive electrode in an adjustable delay manner includes:
turning on the at least one conductive electrode in the adjustable delay manner following turning on the gate in a process of switching the transistor from the OFF state to the ON state; or
turning off the gate before turning off the at least one conductive electrode in the adjustable delay manner in a process of switching the transistor from the ON state to the OFF state.

18. The method according to claim 16, wherein the adjusting of the switching characteristics of the transistor by turning on or off at least one conductive electrode in an adjustable delay manner includes:
sequentially turning on the plurality of conductive electrodes in the adjustable delay manner following turning on the gate in a process of switching the transistor from the OFF state to the ON state; or
turning off the gate before sequentially turning off the plurality of conductive electrodes in the adjustable delay manner in a process of switching the transistor from the ON state to the OFF state.

19. The method according to claim 16, wherein the adjusting of the switching characteristics of the transistor by turning on or off at least one conductive electrode in an adjustable delay manner includes:
sequentially turning on the plurality of conductive electrodes in the adjustable delay manner after turning on the gate and following a predetermined turn-on delay in a process of switching the transistor from the OFF state to the ON state; or
turning off the gate following a predetermined turn-off delay after sequentially turning off the plurality of conductive electrodes in the adjustable delay manner in a process of switching the transistor from the ON state to the OFF state.

20. An electronic device, comprising
a transistor, including:
a substrate,
a source, a drain, and a drain region on the substrate,
an insulating layer on the substrate and the drain region,
a gate on the insulating layer,
a plurality of conductive electrodes arranged on a side of the insulating layer away from the substrate, and
an active integrated circuit electrically connected to the plurality of conductive electrodes, wherein
the active integrated circuit is configured to adjust switching characteristics of the transistor by controlling the plurality of conductive electrodes in a process of switching the transistor from a first switching state to a second switching state, the first switching state is an ON state and the second switching state is an OFF state, or the first switching state is an OFF state and the second switching state is an ON state.
